(19) United States
(12) Patent Application Publication
(10) Pub. No.: US 2023/0223397 A1
(43) Pub. Date: Jul. 13, 2023

(54) ELECTROSTATIC PROTECTION STRUCTURE AND METHOD FOR FABRICATING ELECTROSTATIC PROTECTION STRUCTURE

(71) Applicant: CHANGXIN MEMORY TECHNOLOGIES, INC., Hefei (CN)

(72) Inventor: Bin SONG, Hefei (CN)

(21) Appl. No.: 18/150,199

(22) Filed: Jan. 5, 2023

(30) Foreign Application Priority Data
Jan. 11, 2022 (CN) 202210025304.8

(51) Int. Cl. H01L 27/02; H01L 21/8238

(52) U.S. Cl. CPC H01L 27/0255; H01L 21/823814

(57) ABSTRACT

Embodiments provide an electrostatic protection structure and a method for fabricating the electrostatic protection structure. The electrostatic protection structure includes: a first diode structure, where a first terminal of the first diode structure is connected to a ground terminal, and a second terminal of the first diode structure is connected to a signal terminal; and a second diode structure adjacent to the first diode structure, where a first terminal of the second diode structure is connected to a power supply terminal, and a second terminal of the second diode structure is connected to the signal terminal. A breakdown voltage of the first diode structure and/or a breakdown voltage of the second diode structure is less than a preset threshold. The technical solutions improves electrostatic discharge protection capability of an input/output terminal of an integrated circuit by doping the first diode structure or the second diode structure.

### CROSS-REFERENCE TO RELATED APPLICATION

This application claims priority to Chinese Patent Application No. 202210025304.8, titled “ELECTROSTATIC PROTECTION STRUCTURE AND METHOD FOR FABRICATING ELECTROSTATIC PROTECTION STRUCTURE” and filed to the State Patent Intellectual Property Office on Jan. 11, 2022, the entire contents of which are incorporated herein by reference.

### TECHNICAL FIELD

The present disclosure relates to the field of integrated circuit electrostatic protection technology, and more particularly, to an electrostatic protection structure and a method for fabricating the electrostatic protection structure.

### BACKGROUND

With the development of large scale integrated circuits (LSICs), critical dimensions of the integrated circuits are continuously decreasing, and harms caused by electrostatic discharge to the integrated circuits become easier and easier. Generally, electrostatic discharge (ESD) protection circuits are employed to protect the integrated circuits. Four modes of ESD protection of the integrated circuits are: a PS mode, in which positive charges flow in from an input terminal (I/O) and flow out from a ground terminal (VS S); an NS mode, in which negative charges flow in from the input terminal (I/O) and flow out from the ground terminal VSS; a PD mode (the positive charges flow in from IO and flow out from a power supply terminal (VDD)); and an ND mode (the negative charges flow in from IO and flows out from VDD).

However, because input/output terminals of the integrated circuits generally adopt the smallest process dimension, layout of electrostatic protection circuits around the input/output terminals has limitations, and metal connecting wires in the PS mode or ND mode are the longest, which leads to the largest parasitic resistance and becomes the weakest point of electrostatic protection capability.

Therefore, it is a to-be-solved technical problem to improve the ESD protection capability of the input/output terminals of the integrated circuits.

### SUMMARY

The present disclosure is to provide an electrostatic protection structure and a method for fabricating the electrostatic protection structure.

The present disclosure provides an electrostatic protection structure, which includes a first diode structure and a second diode structure. A first terminal of the first diode structure is connected to a ground terminal, and a second terminal of the first diode structure is connected to a signal terminal. The second diode structure is adjacent to the first diode structure, where a first terminal of the second diode structure is connected to a power supply terminal, and a second terminal of the second diode structure is connected to the signal terminal. A breakdown voltage of the first diode structure and/or a breakdown voltage of the second diode structure is less than a preset threshold.

The present disclosure also provides a method for fabricating an electrostatic protection structure. The method comprises: providing a substrate; forming a first diode substructure and a second diode substructure on the substrate; performing ion implantation on the first diode substructure to form a first diode structure; and/or performing ion implantation on the second diode substructure to form a second diode structure. A reverse breakdown voltage of the first diode structure and/or the second diode structure is less than a reverse breakdown voltage of the first diode substructure and/or the second diode substructure.

It is to be understood that the above general description and the detailed description below are merely exemplary and explanatory, and do not limit the present disclosure. Technologies, methods and devices known to those of ordinary skill in the related art may not be discussed in detail, but where appropriate, the technologies, the methods and the devices should be considered as part of the authorized specification.

### BRIEF DESCRIPTION OF THE DRAWINGS

FIG. 1 is a schematic diagram of an electrostatic protection structure according to an embodiment of the present disclosure;

FIG. 2 is a schematic diagram of a first diode structure in an electrostatic protection circuit according to an embodiment of the present disclosure;

FIG. 3 is a schematic diagram of an electrostatic protection structure according to an embodiment of the present disclosure;

FIG. 4 is a schematic diagram of a second diode structure in the electrostatic protection circuit according to an embodiment of the present disclosure;

FIG. 5 is a schematic diagram of a method for fabricating an electrostatic protection structure according to an embodiment of the present disclosure;

FIG. 6 is a schematic diagram showing a first diode substructure and a second diode substructure according to an embodiment of the present disclosure;

FIG. 7 is a schematic diagram showing a first diode substructure and a second diode substructure according to another embodiment of the present disclosure; and

FIG. 8 is a schematic diagram showing a first diode substructure and a second diode substructure according to yet another embodiment of the present disclosure.

### DETAILED DESCRIPTION

An electrostatic protection structure and a method for fabricating the electrostatic protection structure provided by the embodiments of the present disclosure are described in detail below with reference to the accompanying drawings. The following description of at least one exemplary embodiment is actually merely illustrative, and in no way serves as any limitation on the present disclosure and application or use thereof. That is, it will be understood by those skilled in the art that they illustrate only exemplary embodiments that may be used for implementation, but are not intended to be exhaustive. In addition, unless otherwise stated, the relative arrangement of the components and steps set forth in these embodiments do not limit the scope of the present disclosure.

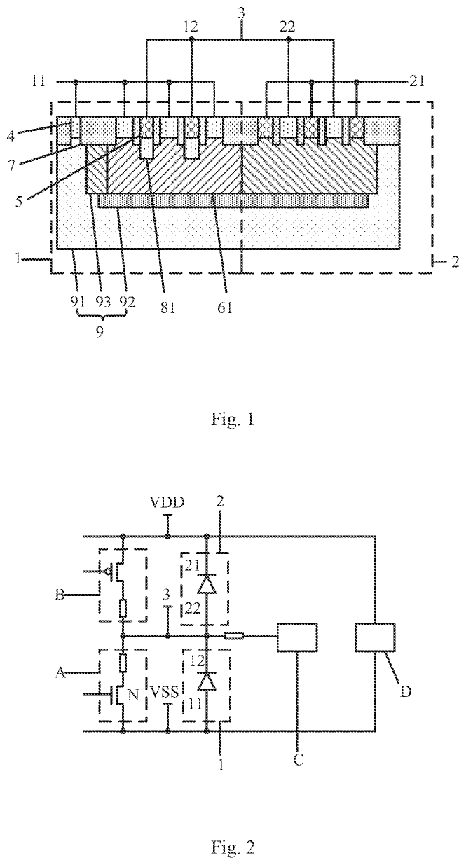

FIG. 1 is a schematic diagram of an electrostatic protection structure according to an embodiment of the present disclosure. Referring to FIG. 1, the electrostatic protection structure includes a first diode structure 1 and a second diode structure 2. A first terminal 11 of the first diode structure 1 is connected to a ground terminal, and a second terminal 12 of the first diode structure 1 is connected to a signal terminal 3. The second diode structure 2 is adjacent to the first diode structure 1, a first terminal 21 of the second diode structure 2 is connected to a power supply terminal, and a second terminal 22 of the second diode structure 2 is connected to a signal terminal 3. A breakdown voltage of the first diode structure 1 is less than a preset threshold. In this embodiment, the preset threshold of the breakdown voltage is 4 V.

In some embodiments, the first diode structure 1 comprises: P-type regions 4, an N-type region 5, and a P-well 61. Each of the P-type regions 4 serves as the first terminal 11 of the first diode structure 1, and the N-type region 5 serves as the second terminal 12 of the first diode structure 1, where the P-well 61 and the N-type region 5 form a PN junction. As a lead-out structure of the P-well 61, the P-type region 4 is connected to the ground terminal, and a doping concentration of the P-type region 4 is greater than that of the P-well 61 to reduce a contact resistance, where a shallow trench isolation structure 7 is provided between adjacent two of the P-type regions 4. The shallow trench isolation structure 7 is configured to isolate the adjacent P-type region 4 or to isolate the N-type region 5 from the P-type region 4, and a depth of the shallow trench isolation structure 7 is greater than a depth of the P-type region 4 and a depth of the N-type region 5, to implement electrical isolation. The shallow trench isolation structure 7 comprises an oxide layer, such as silicon oxide. In some embodiments, the shallow trench isolation structure 7 further comprises a silicon nitride layer. The silicon oxide and the silicon nitride layer are formed in sequence at a bottom and a side wall of a shallow trench, and then an oxide is deposited in the trench to form the shallow trench isolation structure 7. Shaped like a strip, the shallow trench isolation structure 7 is arranged between the P-type region 4 and the N-type region 5 and is distributed along a side wall extension direction of the P-type region 4 and the N-type region 5.

In some embodiments, the first diode structure 1 further comprises a first doped region 81 positioned in the P-well 61 and below the N-type region 5. Doping ions of the P-type region 4 are boron ions, a type of doping ions in the first doped region 81 is identical to a type of the doping ions in the P-type region 4, and an ion doping concentration of the first doped region 81 is greater than that of the P-well 61.

In some embodiments, the electrostatic protection structure further comprises a substrate 9. The substrate 9 comprises a semiconductor substrate 91, a deep N-well layer 92 positioned on the semiconductor substrate, and/or a second N-well 93 positioned beside the first diode 1 and away from a direction of the second diode 2.

FIG. 2 is a schematic diagram of a first diode structure in an electrostatic protection circuit according to an embodiment of the present disclosure. Referring to FIG. 2, the electrostatic protection circuit includes a pull-down circuit A, a pull-up circuit B, a load circuit C, a clamp power supply D, the first diode structure 1, and the second diode structure 2. The first terminal 11 of the first diode structure 1 is connected to a ground terminal VSS, and the second terminal 12 of the first diode structure 1 is connected to the signal terminal 3. The first terminal 21 of the second diode structure 2 is connected to a power supply terminal VDD, and the second terminal 22 of the second diode structure 2 is connected to the signal terminal 3. In a PS mode, current flows in from the signal terminal 3. If the first diode is subjected to avalanche breakdown and the breakdown voltage is above 10 V, positive charges may reach the ground terminal through the second diode structure 2 and the clamp power supply D. Because of a longer path, existence of a parasitic resistance may cause a voltage drop between the signal terminal 3 and the ground terminal VSS to be much greater than a source-drain breakdown voltage of an N-channel metal oxide semiconductor (NMOS) transistor N in the pull-down circuit A, which causes the NMOS transistor N in the pull-down circuit A to be damaged. By doping the first diode structure 1, the positive charges flow in from the signal terminal 3 and breaks down the first diode at the breakdown voltage of about 4V, such that the voltage drop between the signal terminal 3 and the ground terminal VSS is clamped at about 4V, to protect the NMOS transistor N in the pull-down circuit A.

In the above technical solutions, by additionally doping the first diode structure 1, a first doped region 81 having a higher doping concentration is formed, such that the P-well 61, the first doped region 81 and the N-type region 5 form a PN junction having a higher doping concentration, an avalanche breakdown with a higher breakdown voltage occurring in a PN junction with a lower doping concentration is changed into Zener breakdown with a lower breakdown voltage occurring in a PN junction with a higher doping concentration, to reduce a reverse breakdown voltage of the first diode structure 1, enhance voltage clamping capability of the first diode structure, and protect the NMOS transistor N in the pull-down circuit A, thereby improving electrostatic discharge (ESD) protection capability of an input/output terminal of an integrated circuit.

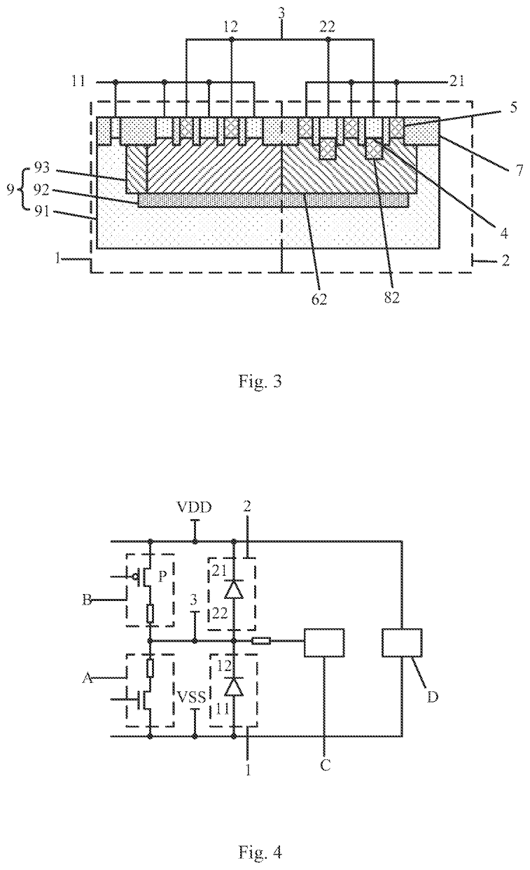

FIG. 3 is a schematic diagram of an electrostatic protection structure according to an embodiment of the present disclosure. Referring to FIG. 3, the electrostatic protection structure includes a first diode structure 1 and a second diode structure 2. A first terminal 11 of the first diode structure 1 is connected to a ground terminal, and a second terminal 12 of the first diode structure 1 is connected to a signal terminal 3. The second diode structure 2 is adjacent to the first diode structure 1, a first terminal 21 of the second diode structure 2 is connected to a power supply terminal, and a second terminal 22 of the second diode structure 2 is connected to the signal terminal 3. A breakdown voltage of the second diode structure 2 is less than a preset threshold. In this embodiment, the preset threshold of the breakdown voltage is 4 V.

In some embodiments, the second diode structure 2 comprises: P-type regions 4, N-type regions 5, and a first N-well 62. Each of the N-type regions 5 serves as the first terminal 21 of the second diode structure 2, and the P-type region 4 serves as the second terminal 22 of the second diode structure, where the first N-well 62 and the P-type region 4 form a PN junction. As a lead-out structure of the first N-well 62, the N-type region 5 is connected to the power supply terminal, and a doping concentration of the N-type region 5 is greater than that of the first N-well 62 to reduce a contact resistance, where a shallow trench isolation structure 7 is provided between adjacent two of the N-type regions 5. The shallow trench isolation structure 7 is configured to isolate the adjacent P-type region 4 or to isolate the N-type region 5 from the P-type region 4, and a depth of the shallow trench isolation structure 7 is greater than a depth of the P-type region 4 and a depth of the N-type region 5, to implement electrical isolation. The shallow trench isolation structure 7 comprises an oxide layer, such as silicon oxide. In some embodiments, the shallow trench isolation structure 7 further comprises a silicon nitride layer. The silicon oxide and the silicon nitride layer are formed in sequence at a bottom and a side wall of a shallow trench, and then an oxide is deposited in the trench to form the shallow trench isolation structure 7. Shaped like a strip, the shallow trench isolation structure 7 is arranged between the P-type region 4 and the N-type region 5 and is distributed along a side wall extension direction of the P-type region 4 and the N-type region 5.

In some embodiments, the second diode structure 2 further comprises a second doped region 82 positioned in the first N-well 62 and below the P-type region 4. Doping ions of the N-type region 5 are phosphorus ions or arsenic ions, a type of doping ions in the second doped region 82 is identical to a type of the doping ions in the N-type region 5, and the ion doping concentration of the second doped region 82 is greater than that of the first N-well 62.

In some embodiments, the electrostatic protection structure further comprises a substrate 9. The substrate 9 comprises a semiconductor substrate 91, a deep N-well layer 92 positioned on the semiconductor substrate, and/or a second N-well 93 positioned beside the first diode 1 and away from a direction of the second diode 2.

FIG. 4 is a schematic diagram of a second diode structure in the electrostatic protection circuit according to an embodiment of the present disclosure. Referring to FIG. 4, the electrostatic protection circuit includes a pull-down circuit A, a pull-up circuit B, a load circuit C, a clamp power supply D, the first diode structure 1, and the second diode structure 2. The first terminal 11 of the first diode structure 1 is connected to a ground terminal VSS, and the second terminal 12 of the first diode structure 1 is connected to the signal terminal 3. The first terminal 21 of the second diode structure 2 is connected to a power supply terminal VDD, and the second terminal 22 of the second diode structure 2 is connected to the signal terminal 3. In an ND mode, negative charges flow in from the signal terminal 3. If the second diode is subjected to avalanche breakdown and the breakdown voltage is above 10 V, the current may reach the ground terminal through the clamp power supply D and the first diode structure 1. Because of a longer path, existence of the parasitic resistance may cause a voltage drop between the signal terminal 3 and the power supply terminal VDD to be much greater than a source-drain breakdown voltage of a P-channel metal oxide semiconductor (PMOS) transistor P in the pull-up circuit B, which causes the PMOS transistor P in the pull-up circuit B to be damaged. By doping the second diode structure 2, the negative charges flow in from the signal terminal 3 and breaks down the second diode at the breakdown voltage of about 4V, such that the voltage drop between the signal terminal 3 and the power supply terminal VDD is clamped at about 4V, to protect the PMOS transistor P in the pull-up circuit B.

In the above technical solutions, by additionally doping the second diode structure 2, a second doped region 82 having a higher doping concentration is formed, such that the N-well 62, the second doped region 82 and the P-type region 4 form a PN junction having a higher doping concentration, an avalanche breakdown with a higher breakdown voltage occurring in a PN junction with a lower doping concentration is changed into Zener breakdown with a lower breakdown voltage occurring in a PN junction with a higher doping concentration, to reduce a reverse breakdown voltage of the second diode structure 2, enhance voltage clamping capability of the second diode structure, and protect the PMOS transistor P in the pull-up circuit B, thereby improving the electrostatic discharge (ESD) protection capability of the input/output terminal of the integrated circuit.

In some other embodiments, the second doped region 82 in the second diode structure 2 is doped with the phosphorus ions or the arsenic ions while the first doped region 81 in the first diode structure 1 is doped with the boron ions. The NMOS transistor N in the pull-down circuit A is protected in the case of failure of the PS mode, and the PMOS transistor P in the pull-up circuit B is protected in the case of failure of the ND mode, thereby improving the ESD protection capability of the input/output terminal of the integrated circuit.

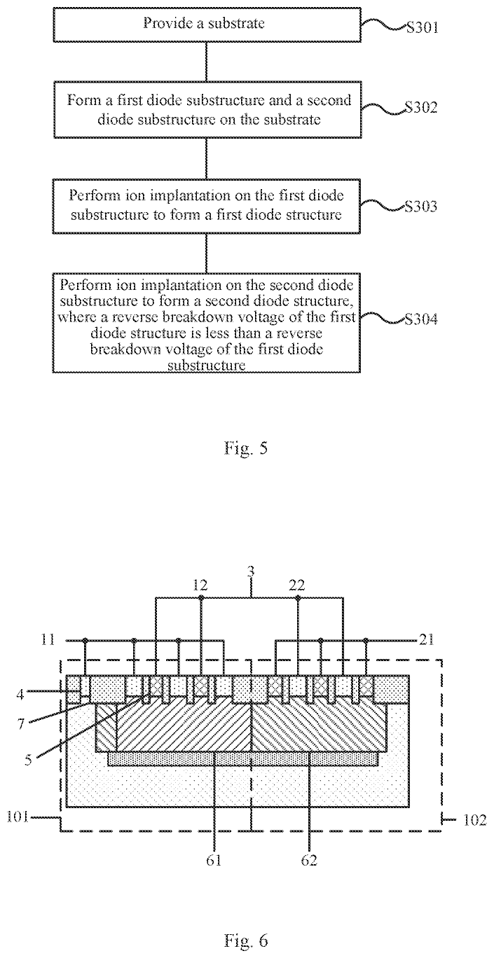

FIG. 5 is a schematic diagram of a method for fabricating an electrostatic protection structure according to an embodiment of the present disclosure. Referring to FIG. 5, the method for fabricating the electrostatic protection structure comprises: Step S101 of providing a substrate; Step S102 of forming a first diode substructure and a second diode substructure on the substrate; S103 of performing ion implantation on the first diode substructure to form a first diode structure; and S104 of performing ion implantation on the second diode substructure to form a second diode structure. A reverse breakdown voltage of the first diode structure and/or the second diode structure is less than a reverse breakdown voltage of the first diode substructure and/or the second diode substructure. In some other embodiments, ion implantation may be only performed on the first diode substructure or the second diode substructure.

Step S101: providing a substrate. Forming the substrate comprises: providing a semiconductor substrate, forming a deep N-well layer on the semiconductor substrate, and/or forming a second N-well positioned beside the first diode structure and away from a direction of the second diode structure.

Step S102: forming the first diode substructure and the second diode substructure on the substrate. FIG. 6 is a schematic diagram showing a first diode substructure and a second diode substructure according to an embodiment of the present disclosure. Referring to FIG. 6, the first diode substructure 101 includes a P-type region 4, an N-type region 5, and a P-well 61. Serving as an anode of the first diode substructure, i.e., the first terminal 11 of the first diode structure, the P-type region 4 is connected to the ground terminal. Serving as a cathode of the first diode substructure, i.e., the second terminal 12 of the first diode structure, the N-type region 5 is connected to the signal terminal 3. The P-well 61 and the N-type region 5 form a PN junction. The second diode substructure includes a P-type region 4, an N-type region 5, and a first N-well 62. Serving as a cathode of the second diode substructure, i.e., the first terminal 21 of the second diode structure, the N-type region 5 is connected to the power supply terminal. Serving as an anode of the second diode substructure, i.e., the second terminal 22 of the second diode structure, the P-type region 4 is connected to the signal terminal 3. The first N-well 62 and the N-type region 5 form a PN junction.

Step S103: performing ion implantation on the first diode substructure to form the first diode structure. FIG. 1 is a schematic diagram of an electrostatic protection structure according to an embodiment of the present disclosure. Referring to FIG. 1, a heavily doped region 81 of a first doping type is formed below the cathode of the first diode substructure to form the first diode structure 1, to reduce the reverse breakdown voltage of the first diode structure 1. The first diode structure 1 comprises: P-type regions 4, an N-type region 5, and a P-well 61. Each of the P-type regions 4 serves as the first terminal 11 of the first diode structure 1, and the N-type region 5 serves as the second terminal 12 of the first diode structure 1, where the P-well 61 and the N-type region 5 form a PN junction. As a lead-out structure of the P-well 61, the P-type region 4 is connected to the ground terminal, and a doping concentration of the P-type region 4 is greater than that of the P-well 61 to reduce the contact resistance. The performing ion implantation on the first diode substructure comprises: forming a heavily doped region 81 of a first doping type below the cathode of the first diode substructure to reduce a reverse breakdown voltage of the first diode structure. The first doped region 81 is positioned in the P-well 61 and below the N-type region 5. Doping ions of the P-type region 4 are boron ions, a type of doping ions in the first doped region 81 is identical to a type of the doping ions in the P-type region 4, and an ion doping concentration of the first doped region 81 is greater than that of the P-well 61.

Step S104: performing ion implantation on the second diode substructure to form a second diode structure. FIG. 3 is a schematic diagram of an electrostatic protection structure according to an embodiment of the present disclosure. Referring to FIG. 3, a heavily doped region 82 of a second doping type is formed below the anode of the second diode substructure to form the second diode structure 2, to reduce the reverse breakdown voltage of the second diode structure 2. In this embodiment, the preset threshold of the breakdown voltage is 4 V. The second diode structure 2 comprises: P-type regions 4, N-type regions 5, and a first N-well 62. Each of the N-type regions 5 serves as the first terminal 21 of the second diode structure 2, and the P-type region 4 serves as the second terminal 22 of the second diode structure, where the first N-well 62 and the P-type region 4 form a PN junction. As a lead-out structure of the first N-well 62, the N-type region 5 is connected to the power supply terminal, and a doping concentration of the N-type region 5 is greater than that of the first N-well 62 to reduce the contact resistance. The performing ion implantation on the second diode substructure includes: forming a second doped region 82 of a second doping type below the anode of the second diode substructure. The second doped region 82 is positioned within the first N-well 62 and below the P-type region 4, to reduce the reverse breakdown voltage of the second diode structure 2. Doping ions of the N-type region 5 are phosphorus ions or arsenic ions, a type of doping ions in the second doped region 82 is identical to a type of the doping ions in the N-type region 5, and the ion doping concentration of the second doped region 82 is greater than that of the first N-well 62.

According to the above technical solutions, the boron ions are doped below the cathode of the first diode substructure 101 to form a heavily doped region 81 of a first doping type, such that the P-well 61, the heavily doped region 81 and the N-type region 5 form a PN junction with a higher doping concentration. Phosphorus ions or arsenic ions are doped under the anode of the second diode substructure to form a heavily doped region 82 of a second doping type, such that the N-well 62, the heavily doped region 82 and the P-type region 4 form a PN junction with a higher doping concentration. An avalanche breakdown with a higher breakdown voltage occurring in the PN junction with a lower doping concentration is changed into Zener breakdown with a lower breakdown voltage occurring in the PN junction with a higher doping concentration, to reduce the reverse breakdown voltage of the first diode structure 1 or the second diode structure 2, and enhance the voltage clamping capability, thereby improving the electrostatic discharge (ESD) protection capability of the input/output terminal of the integrated circuit.

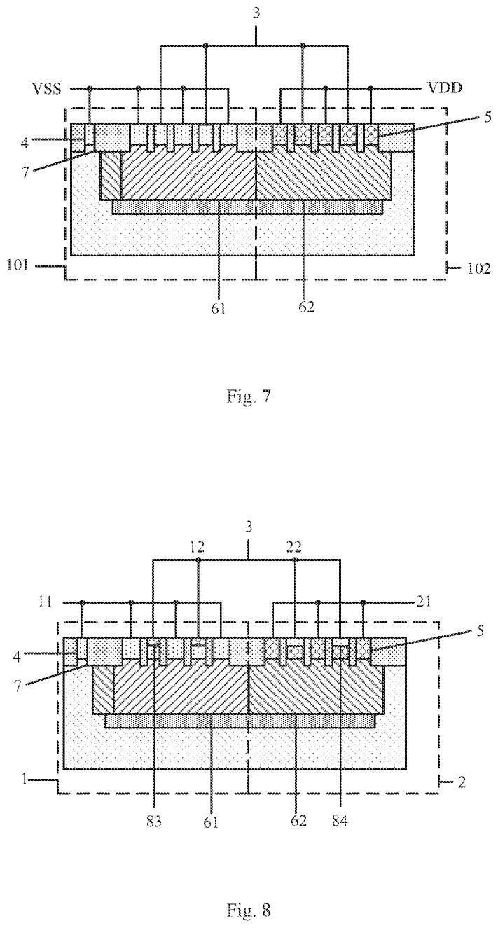

FIG. 7 is a schematic diagram showing a first diode substructure and a second diode substructure according to an embodiment of the present disclosure. Referring to FIG. 7, the first diode substructure 101 includes a P-well 61 and a plurality of P-type regions 4, where a shallow trench isolation structure 7 is formed between adjacent P-type regions 4. Part of the P-type region 4 serves as the anode of the first diode substructure to connect the ground terminal VSS. The second diode substructure 102 comprises a first N-well 62 and a plurality of N-type regions, and a shallow trench isolation structure 7 is formed between adjacent two of the plurality of N-type regions. Part of the N-type region 5 serves as the anode of the second diode substructure to connect the power supply terminal VDD. The shallow trench isolation structure 7 comprises an oxide layer, such as silicon oxide. In some embodiments, the shallow trench isolation structure 7 further comprises a silicon nitride layer. The silicon oxide and the silicon nitride layer are formed in sequence at a bottom and a side wall of a shallow trench, and then an oxide is deposited in the trench to form the shallow trench isolation structure 7. Shaped like a strip, the shallow trench isolation structure 7 is arranged between the P-type region 4 and the N-type region 5 and is distributed along a side wall extension direction of the P-type region 4 and the N-type region 5.

FIG. 8 is a schematic diagram showing a first diode substructure and a second diode substructure according to yet another embodiment of the present disclosure. Referring to FIG. 8, the performing ion implantation on the first diode substructure comprises: forming a third doped region 83 of a third doping type on part of the P-type region 4 of the first diode substructure. Serving as the cathode of the first diode structure, i.e., the second terminal 12 of the first diode structure, the third doped region 83 of the third doping type is connected to the signal terminal 3. Serving as the first terminal 11 of the first diode structure, part of the P-type region 4 not doped with the third type is connected to the ground terminal. The P-well 61, part of the P-type region, and the third doped region 83 of the third doping type constitute the PN junction. The third doped region 83 may be formed by means of a process for fabricating a source-drain contact plug of the NMOS transistor. When fabricating the NMOS transistor, to reduce the contact resistance of the source-drain contact plug and increase electrical conductivity, an additional N-type heavy doping may be performed on the source-drain region. Therefore, the third doped region 83 may be formed simultaneously without additional process steps. The performing ion implantation on the second diode substructure comprises: forming a fourth doped region 84 of a fourth doping type on part of the N-type region 5 of the second diode substructure. Serving as the cathode of the second diode structure, i.e., the second terminal 22 of the second diode structure, the fourth doped region 84 of the fourth doping type is connected to the signal terminal. The N-well 62, part of the N-type region and the fourth doped region of the fourth doping type constitute the PN junction. The fourth doped region 84 may be formed by means of a process for fabricating a source-drain contact plug of the PMOS transistor. When fabricating the PMOS transistor, to reduce the contact resistance of the source-drain contact plug and increase the electrical conductivity, an additional P-type heavy doping may be performed on the source-drain region. Therefore, the fourth doped region 84 may be formed simultaneously without additional process steps.

In some other embodiments, only the first diode substructure may be ion implanted to form the third doped region 83, or only the second diode substructure may be ion implanted to form the fourth doped region 84.

What is mentioned above merely refers to some embodiments of the present disclosure. It is to be pointed out that to those of ordinary skill in the art, various improvements and embellishments may be made without departing from the principle of the present disclosure, and these improvements and embellishments are also deemed to be within the scope of protection of the present disclosure.

What is claimed is:

1. An electrostatic protection structure, comprising:
a first diode structure, wherein a first terminal of the first diode structure is connected to a ground terminal, and a second terminal of the first diode structure is connected to a signal terminal; and
a second diode structure adjacent to the first diode structure, wherein a first terminal of the second diode structure is connected to a power supply terminal, and a second terminal of the second diode structure is connected to the signal terminal;
wherein a breakdown voltage of the first diode structure and/or a breakdown voltage of the second diode structure is less than a preset threshold.

2. The electrostatic protection structure according to claim 1, wherein the first diode structure comprises: P-type regions, an N-type region, and a P-well; each of the P-type regions serves as the first terminal of the first diode structure, the N-type region serves as the second terminal of the first diode structure, the P-well and the N-type region form a PN junction, and a shallow trench isolation structure is provided between adjacent two of the P-type regions.

3. The electrostatic protection structure according to claim 2, wherein the first diode structure further comprises: a first doped region positioned in the P-well and below the N-type region.

4. The electrostatic protection structure according to claim 3, wherein a type of doping ions in the first doped region is identical to a type of doping ions in the P-type region, comprising boron ions.

5. The electrostatic protection structure according to claim 1, wherein the second diode structure comprises: a P-type region, N-type regions, and a first N-well; each of the N-type regions serves as the first terminal of the second diode structure, the P-type region serves as the second terminal of the second diode structure, the first N-well and the P-type region form a PN junction, and a shallow trench isolation structure is provided between adjacent two of the N-type regions.

6. The electrostatic protection structure according to claim 5, wherein the second diode structure further comprises: a second doped region positioned in the first N-well and below the P-type region.

7. The electrostatic protection structure according to claim 6, wherein a type of doping ions in the second doped region is identical to a type of doping ions in the N-type region, comprising phosphorus ions and arsenic ions.

8. The electrostatic protection structure according to claim 1, further comprising a substrate, wherein the substrate comprises a semiconductor substrate, a deep N-well layer positioned on the semiconductor substrate, and/or a second N-well positioned beside the first diode structure and away from a direction of the second diode structure.

9. A method for fabricating an electrostatic protection structure, comprises:
providing a substrate;
forming a first diode substructure and a second diode substructure on the substrate;
performing ion implantation on the first diode substructure to form a first diode structure;
and/or performing ion implantation on the second diode substructure to form a second diode structure;
wherein a reverse breakdown voltage of the first diode structure and/or the second diode structure is less than a reverse breakdown voltage of the first diode substructure and/or the second diode substructure.

10. The method for fabricating the electrostatic protection structure according to claim 9, wherein forming the substrate comprises: providing a semiconductor substrate, forming a deep N-well layer on the semiconductor substrate, and/or forming a second N-well positioned beside the first diode structure and away from a direction of the second diode structure.

11. The method for fabricating the electrostatic protection structure according to claim 10, wherein the first diode substructure comprises: a P-type region, an N-type region and a P-well; the P-type region serves as an anode of the first diode substructure to connect a ground terminal, the N-type region serves as a cathode of the first diode substructure to connect a signal terminal, and the P-well and the N-type region form a PN junction.

12. The method for fabricating the electrostatic protection structure according to claim 11, wherein the performing ion implantation on the first diode substructure comprises: forming a heavily doped region of a first doping type below the cathode of the first diode substructure to reduce a reverse breakdown voltage of the first diode structure.

13. The method for fabricating the electrostatic protection structure according to claim 12, wherein ion implantation is performed on the heavily doped region of the first doping type by using ions having the same type as doping ions in the P-well, a doping concentration being greater than a doping concentration of the P-well.

14. The method for fabricating the electrostatic protection structure according to claim 10, wherein the second diode substructure comprises a P-type region, an N-type region, and a first N-well; the N-type region serves as a cathode of the second diode substructure to connect a power supply terminal, the P-type region serves as an anode of the second diode substructure to connect a signal terminal, and the first N-well and the P-type region form a PN junction.

15. The method for fabricating the electrostatic protection structure according to claim 14, wherein the performing ion implantation on the second diode substructure comprises: forming a heavily doped region of a second doping type below the anode of the second diode substructure to reduce a reverse breakdown voltage of the second diode structure.

16. The method for fabricating the electrostatic protection structure according to claim 15, wherein ion implantation is performed on the heavily doped region of the second doping type by using ions having the same type as doping ions in the N-well, a doping concentration being greater than a doping concentration of the N-well.

17. The method for fabricating the electrostatic protection structure according to claim 10, wherein the first diode substructure comprises a P-well and a plurality of P-type regions, and a shallow trench isolation structure is formed between adjacent two of the plurality of P-type regions.

18. The method for fabricating the electrostatic protection structure according to claim 10, wherein the second diode substructure comprises a first N-well and a plurality of N-type regions, and a shallow trench isolation structure is formed between adjacent two of the plurality of N-type regions.
